(19) United States
(12) Patent Application Publication
(10) Pub. No.: US 2025/0087603 A1
(43) Pub. Date: Mar. 13, 2025

(54) SEMICONDUCTOR PACKAGE

(71) Applicant: SAMSUNG ELECTRONICS CO., LTD., Suwon-si (KR)

(72) Inventors: Young Lyong Kim, Suwon-si (KR); Hyun Soo Chung, Suwon-si (KR)

(21) Appl. No.: 18/616,875

(22) Filed: Mar. 26, 2024

(30) Foreign Application Priority Data
Sep. 13, 2023 (KR) 10-2023-0121731

(51) Int. Cl. H01L 23/64; H01L 23/00; H01L 23/28; H01L 23/498; H01L 23/538; H01L 25/065

(52) U.S. Cl. CPC H01L 23/642; H01L 23/28; H01L 23/49816; H01L 23/49822; H01L 23/49827; H01L 23/5381; H01L 23/562; H01L 24/16; H01L 24/32; H01L 24/73; H01L 25/0655; H01L 25/0657; H01L 2224/16145; H01L 2224/16227; H01L 2224/32145; H01L 2224/32225; H01L 2224/73204

(57) ABSTRACT

A semiconductor package includes an interposer structure extending in a first direction and including an inner area and an outer area defined by an inner area, a first semiconductor chip mounted on the inner area and electrically connected to the interposer structure, a plurality of bumps disposed between the first semiconductor chip and the interposer structure, and contacting each of the first semiconductor chip and the interposer structure, an underfill filling a space between the interposer structure and the first semiconductor chip and covering the plurality of bumps; and a mold layer disposed on the outer area and surrounding the first semiconductor chip, wherein the interposer structure includes a decoupling capacitor, wherein a ratio of a length in the first direction of the first semiconductor chip to a length in the first direction of the interposer structure is in a range of 0.9 inclusive to 1 exclusive.

### CROSS-REFERENCE TO RELATED APPLICATION

This application claims priority from Korean Patent Application No. 10-2023-0121731 filed on Sep. 13, 2023 in the Korean Intellectual Property Office, and all the benefits accruing therefrom, under 35 U.S.C. 119, the contents of which are herein incorporated by reference in their entirety.

### TECHNICAL FIELD

The present disclosure relates to semiconductor packaging.

### BACKGROUND

In a semiconductor package with a high-performance semiconductor chip built therein, problems such as system malfunction and performance degradation may occur due to voltage noise generated in a high frequency band.

### SUMMARY

A technical purpose to be achieved by the present disclosure is to provide a semiconductor package with improved reliability. For example, the present disclosure can provide packaging schemes that remove or reduce voltage noise, providing improved Power Integrity (PI) of semiconductor packaging.

The technical purpose of the present disclosure is not limited to the technical purpose as mentioned above, and other technical purposes as not mentioned will be clearly understood by those skilled in the art from descriptions set forth below.

According to some aspects of the present disclosure, there is provided a semiconductor package comprising an interposer structure extending in a first direction and including an inner area and an outer area defined by an inner area, a first semiconductor chip mounted on the inner area and electrically connected to the interposer structure, a plurality of bumps disposed between the first semiconductor chip and the interposer structure, and contacting each of the first semiconductor chip and the interposer structure, an underfill filling a space between the interposer structure and the first semiconductor chip and covering the plurality of bumps; and a mold layer disposed on the outer area and surrounding the first semiconductor chip, wherein the interposer structure includes a decoupling capacitor, wherein a ratio of a length in the first direction of the first semiconductor chip to a length in the first direction of the interposer structure is in a range of 0.9 inclusive to 1 exclusive, wherein the length in the first direction of the interposer structure is equal to a sum of the length in the first direction of the first semiconductor chip and a length in the first direction of the mold layer.

According to some aspects of the present disclosure, there is provided a semiconductor package comprising a circuit substrate extending in a first direction, an interposer structure disposed on the circuit substrate and including an inner area and an outer area defined by the inner area, a plurality of first solder balls disposed between the circuit substrate and the interposer structure and connecting the circuit substrate and the interposer structure to each other, a first semiconductor chip mounted on the inner area and electrically connected to the interposer structure, a plurality of bumps disposed between the first semiconductor chip and the interposer structure, and contacting each of the first semiconductor chip and the interposer structure, an underfill filling a space between the interposer structure and the first semiconductor chip and covering the plurality of bumps and a mold layer disposed on the outer area and surrounding the first semiconductor chip, wherein the mold layer covers an upper surface of the underfill, wherein the mold layer does not cover a side surface of the underfill, wherein the interposer structure includes, an interposer extending in the first direction, an interlayer insulating film disposed on the interposer, a through-via extending through the interposer and to the interlayer insulating film, redistribution layers formed within the interlayer insulating film and a decoupling capacitor formed within the interlayer insulating film and between the through-via and a lowest one of the redistribution layers, wherein a ratio of a length in the first direction of the first semiconductor chip to a length in the first direction of the interposer structure is in a range of 0.9 inclusive to 1 exclusive, wherein the length in the first direction of the interposer structure is equal to a sum of the length in the first direction of the first semiconductor chip and a length in the first direction of the mold layer.

According to some aspects of the present disclosure, there is provided a semiconductor package comprising a circuit substrate, an interposer structure disposed on the circuit substrate, wherein the interposer structure includes, an interposer extending in a first direction, an interlayer insulating film disposed on the interposer, a through-via extending through the interposer and to the interlayer insulating film, redistribution layers formed within the interlayer insulating film and an integrated stack capacitor formed within the interlayer insulating film and between the through-via and a lowest one of the redistribution layers, a plurality of solder balls disposed between the circuit substrate and the interposer structure and connecting the circuit substrate and the interposer structure to each other, an ASIC chip disposed on the interposer structure, a plurality of bumps disposed between the ASIC chip and the interposer structure and connecting the ASIC chip and the interposer structure to each other, an underfill filling a space between the interposer structure and the ASIC chip and covering the plurality of bumps, a mold layer surrounding the underfill and the ASIC chip, wherein the mold layer covers an upper surface of the underfill and does not cover a side surface of the underfill, eee a stiffener spaced apart from the interposer structure and the ASIC chip, wherein the interposer structure includes an inner area and an outer area defined by the inner area, wherein the ASIC chip is disposed on the inner area, and the mold layer is disposed on the outer area, wherein a sum of a length in the first direction of the inner area and a length in the first direction of the outer area is equal to a length in the first direction of the interposer structure, wherein a side surface of the mold layer, a side surface of the underfill, and a side surface of the interposer structure are coplanar with each other.

### BRIEF DESCRIPTION OF DRAWINGS

The above and other aspects and features of the present disclosure will become more apparent by describing in detail illustrative examples thereof with reference to the attached drawings, in which:

FIG. 1 is a plan view illustrating an example of a semiconductor package.

FIG. 2 is a cross-sectional view as cut along a line A-A in FIG. 1.

FIG. 3 is an enlarged view of a portion P in FIG. 2.

FIG. 4 is a diagram illustrating an example of a semiconductor package.

FIG. 5 is a diagram illustrating an example of a semiconductor package.

FIG. 6 is a diagram illustrating an example of a semiconductor package.

FIGS. 7 to 21 are drawings sequentially showing an example of a process of manufacturing a semiconductor package.

### DETAILED DESCRIPTIONS

Although terms such as first and second are used to describe various elements or components in the present specification, it goes without saying that these elements or components are not limited by these terms. These terms are used only to distinguish a single element or component from other elements or components. Therefore, it goes without saying that a first element or component referred to below may be a second element or component within the technical idea of the present disclosure.

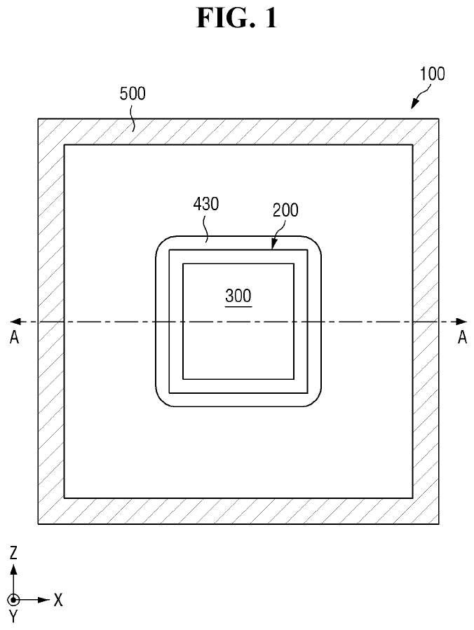

Hereinafter, with reference to FIG. 1 to FIG. 3, a semiconductor package according to some implementations of the present disclosure is described.

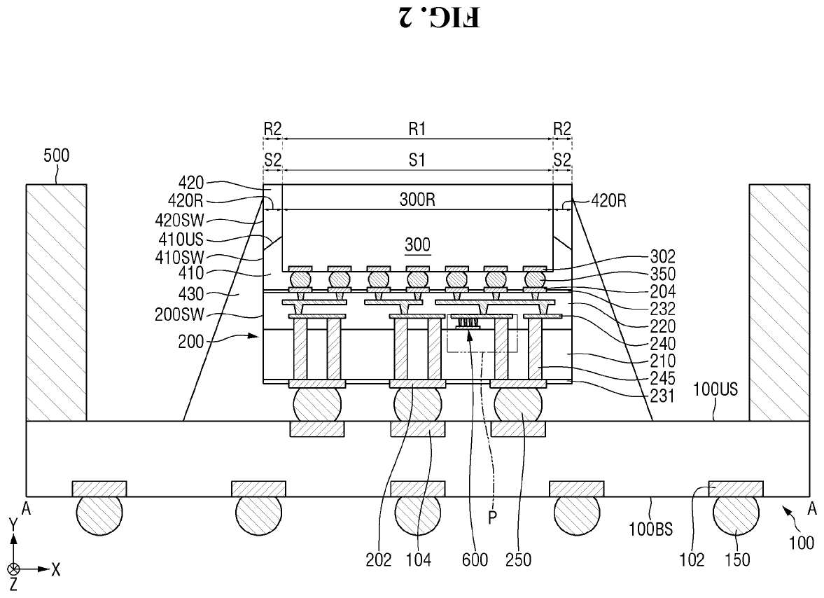

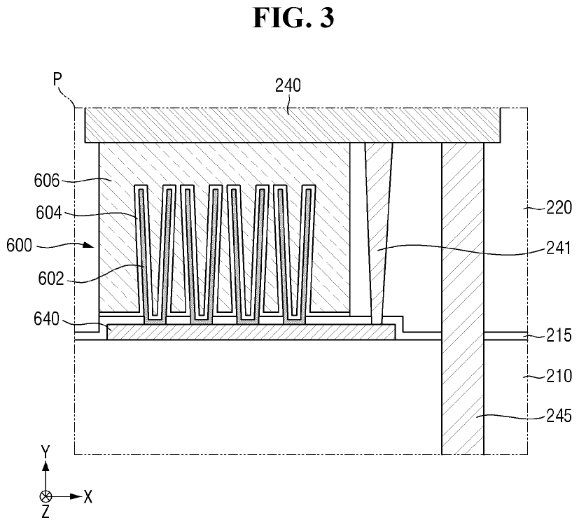

FIG. 1 is an illustrative plan view for illustrating a semiconductor package according to some implementations of the present disclosure. FIG. 2 is a cross-sectional view as cut along a line A-A in FIG. 1. FIG. 3 is an enlarged view of a portion P in FIG. 2.

Referring to FIGS. 1 to 3, the semiconductor package according to some implementations includes a circuit substrate 100, an interposer structure 200, a first semiconductor chip 300, an underfill 410, a mold layer 420, a substrate underfill 430 and a stiffener 500.

The circuit substrate 100 may extend in a first direction X. In the present disclosure, the first direction X, the second direction Y and the third direction Z may intersect each other. The first direction X, the second direction Y, and the third direction Z may be substantially perpendicular to each other. As shown in FIG. 2, the first direction X and the third direction Z may be parallel to a surface of the circuit substrate 100, and the interposer structure 200 and the first semiconductor chip 300 may be stacked on the circuit substrate in second direction Y.

The circuit substrate 100 may be a package substrate. The circuit substrate 100 may be embodied as a printed circuit board (PCB). The circuit substrate 100 may include an upper surface 100US and a lower surface 100BS that are opposite to each other. The upper surface 100US of the circuit substrate 100 may face the interposer structure 200, which will be described later.

The circuit substrate 100 may include a first substrate pad 102 and a second substrate pad 104. Each of the first substrate pad 102 and the second substrate pad 104 may be used to electrically connect the circuit substrate 100 to other components. In some implementations, the first substrate pad 102 may be formed near the lower surface 100BS of the circuit substrate 100, and the second substrate pad 104 may be formed near the upper surface 100US of the circuit substrate 100. The first substrate pad 102 may not be covered with the lower surface 100BS of the circuit substrate 100 so as to be exposed, and the second substrate pad 104 may not be covered with the upper surface 100US of the circuit substrate 100 so as to be exposed. In FIG. 2, it is shown that the number of the first substrate pads 102 is five. However, the present disclosure is not limited thereto. Likewise, it is shown in FIG. 2 that the number of the second substrate pads 104 is three. However, the present disclosure is not limited thereto.

The circuit substrate 100 may be mounted on a main board of an electronic device or the like. For example, a connection terminal 150 contacting the first substrate pad 102 may be provided. The circuit substrate 100 may be mounted on the main board of the electronic device via the connection terminal 150. The circuit substrate 100 may be a BGA (Ball Grid Array) substrate. However, the present disclosure is not limited thereto.

The connection terminal 150 may be, for example, a solder bump. However, the present disclosure is not limited thereto. The connection terminal 150 may have various shapes such as a land, a ball, a pin, a pillar, etc. The number of, a spacing between, and an arrangement of the connection terminals 150 are not limited to those shown, and may vary depending on the implementation.

The interposer structure 200 may extend in the first direction X and be disposed on the upper surface 100US of the circuit substrate 100. The interposer structure 200 may include an upper surface and a lower surface that are opposite to each other. The upper surface of the interposer structure 200 may face the first semiconductor chip 300, which will be described later. The lower surface of the interposer structure 200 may face the circuit substrate 100. The interposer structure 200 may facilitate connection between the circuit substrate 100 and the first semiconductor chip 300, which will be described later, and may prevent warpage of the semiconductor package.

In some implementations, the interposer structure 200 may include an interposer 210, an interlayer insulating film 220, a first passivation film 231, a second passivation film 232, redistribution layers 240, a through-via 245, a first interposer pad 202, a second interposer pad 204, and a decoupling capacitor 600.

The interposer 210 may be provided on the circuit substrate 100. The interposer 210 may be, for example, a silicon (Si) interposer. However, the present disclosure is not limited thereto. The interlayer insulating film 220 may include an insulating material. For example, the interlayer insulating film 220 may include at least one of silicon oxide, silicon nitride, silicon oxynitride, and a low-k material with a lower dielectric constant than that of silicon oxide. However, the present disclosure is not limited thereto.

Each of the first interposer pad 202 and the second interposer pad 204 may be used to electrically connect the interposer structure 200 to other components. For example, the first interposer pad 202 may not be covered with the lower surface of the interposer structure 200 so as to be exposed, and the second interposer pad 204 may not be covered with the upper surface of the interposer structure 200 so as to be exposed. Each of the first interposer pad 202 and the second interposer pad 204 may include, but may be not be limited to, a metal material such as copper (Cu) or aluminum (Al). Within the interposer structure 200, wiring patterns may be formed to electrically connect the first interposer pad 202 and the second interposer pad 204 to each other.

For example, the redistribution layers 240 and the through-via 245 may be formed within the interposer structure 200. The redistribution layers 240 may be disposed within the interlayer insulating film 220. The through-via 245 may extend through the interposer 210 to the interlayer insulating film 220.

The redistribution layers 240 may be electrically connected to the second interposer pad 204. The through-via 245 may be electrically connected to the first interposer pad 202. Thus, the interposer structure 200 and the first semiconductor chip 300 may be electrically connected to each other. Each of the redistribution layers 240 and the through-via 245 may include a metal material such as copper (Cu) or aluminum (Al). However, the present disclosure is not limited thereto.

The decoupling capacitor 600 may be formed between the lowest redistribution layer 240 and the through-via 245, e.g., below the lowest redistribution layer 240 and at a same vertical level as a portion of the through-via 245. The decoupling capacitor 600 may be formed within the interlayer insulating film 220. Referring to FIG. 3, the decoupling capacitor 600 may be formed on a connection pattern 640. The connection pattern 640 may be formed on the interposer 210. The connection pattern 640 may extend along a portion of the upper surface of the interposer 210. The connection pattern 640 may include a conductive material.

In some implementations, an etch stop film 215 may be formed on the connection pattern 640. For example, the etch stop film 215 may be formed conformally along and on a portion of the upper surface of the interposer 210 and the upper surface of the connection pattern 640. The etch stop film 215 may include, for example, silicon nitride. However, the present disclosure is not limited thereto.

The decoupling capacitor 600 may include a lower electrode 602, a capacitor dielectric film 604, and an upper electrode 606.

In some implementations, the lower electrode 602 may contact the connection pattern 640. For example, the lower electrode 602 may extend through the first etch stop film 215 so as to contact the connection pattern 640. For example, a bottom surface of the lower electrode 602 may contact an upper surface of the connection pattern 640. The lower electrode 602 may include a conductive material. For example, the lower electrode 602 may include at least one of titanium (Ti), titanium nitride (TiN), tantalum (Ta), tantalum nitride (TaN), tungsten nitride (WN), metal silicide, and combinations thereof. However, the present disclosure is not limited thereto.

The capacitor dielectric film 604 may be formed on the lower electrode 602. For example, the capacitor dielectric film 604 may extend along a profile of the lower electrode 602.

The capacitor dielectric film 604 may include, for example, silicon oxide, silicon nitride, silicon oxynitride, and/or a high-k material with a higher dielectric constant that of than silicon oxide. The high dielectric constant (high-k) material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The upper electrode 606 may be formed on the capacitor dielectric film 604. The upper electrode 606 may cover the capacitor dielectric film 604. The upper electrode 606 may be spaced apart from the lower electrode 602 by the capacitor dielectric film 604. For example, the capacitor dielectric film 604 may be interposed between the lower electrode 602 and the upper electrode 606. The upper electrode 606 may be electrically connected to the redistribution layers 240. In some implementations, the upper electrode 606 may be electrically connected to the lowest one of the redistribution layers 240.

The upper electrode 606 may include a conductive material. For example, the upper electrode 606 may include at least one of titanium (Ti), titanium nitride (TiN), tantalum (Ta), tantalum nitride (TaN), tungsten nitride (WN), metal silicide, and combinations thereof. However, the present disclosure is not limited thereto.

In some implementations, the upper electrode 606 may include a semiconductor material such as poly silicon (poly Si) or silicon germanium (SiGe).

In some implementations, a connection via 241 may be formed within the interlayer insulating film 220 so as to connect the lower electrode 602 and the redistribution layers 240 to each other. For example, the connection via 241 may extend through the interlayer insulating film 220 so as to connect the upper surface of the connection pattern 640 and a bottom surface of the lowest one of the redistribution layers 240 to each other. Accordingly, the lower electrode 602 may be electrically connected to the redistribution layers 240. The connection via 241 may include conductive material.

Voltages of different levels of may be respectively applied to the lower electrode 602 and the upper electrode 606.

The decoupling capacitor 600 may store charges in the capacitor dielectric film 604 using a difference between the voltage level of the lower electrode 602 and the voltage level of the upper electrode 606.

In some implementations, the decoupling capacitor 600 may be an integrated stack capacitor (ISC). The decoupling capacitor 600 may include at least one stack capacitor.

When the ISC is present in the interposer structure 200, the ISC may operate as a decoupling capacitor to offset a voltage drop effect when the semiconductor chip operates. It can be beneficial to design a power delivery network (PDN) with low power impedance. The presence of the decoupling capacitor within the interposer structure 200 may reduce an inductance to eliminate voltage noise to improve the Power Integrity (PI) of the semiconductor chip.

Referring again to FIG. 2, the interposer structure 200 may be mounted on the upper surface 100US of the circuit substrate 100. For example, a first solder ball 250 may be formed between the circuit substrate 100 and the interposer structure 200. The first solder ball 250 may connect the second substrate pad 104 and the first interposer pad 202 to each other. Accordingly, the circuit substrate 100 and the interposer structure 200 may be electrically connected to each other.

The first solder ball 250 may be embodied as a solder bump including a low melting point metal, such as tin (Sn) and tin alloy. However, the present disclosure is not limited thereto. The first solder ball 250 may have various shapes such as a land, a ball, a pin, or a pillar. The first solder ball 250 may be formed as a single layer or a stack of multiple layers. When the first solder ball 250 is formed as a single layer, the first solder ball 250 may, for example, include tin-silver (Sn—Ag) solder or copper (Cu). When the first solder ball 250 is formed as the stack of multiple layers, the first solder ball 250 may include, for example, copper (Cu) filler and solder. The number of, a spacing between, an arrangement, etc. of the first solder balls 250 are not limited to those shown, and may vary depending on the implementation.

The first passivation film 231 may be disposed on the interposer 210. The first passivation film 231 may extend in an elongate manner along a bottom surface of the interposer 210. The first interposer pad 202 may extend through the first passivation film 231 so as to be connected to the through-via 245.

The second passivation film 232 may be disposed on the interlayer insulating film 220. The second passivation film 232 may extend in an elongate manner along an upper surface of the interlayer insulating film 220. The second interposer pad 204 may extend through the second passivation film 232 so as to be connected to the redistribution layers 240.

In some implementations, a height of the second passivation film 232 in the second direction Y may be smaller than a height of the second interposer pad 204 in the second direction Y. The second interposer pad 204 may protrude in the second direction Y beyond the second passivation film 232 The first interposer pad 202 may protrude in the second direction Y beyond the first passivation film 231.

Each of the first passivation film 231 and the second passivation film 232 may include silicon nitride. Alternatively, or in addition, each of the first passivation film 231 and the second passivation film 232 may include a passivation material, for example, BCB (benzocyclobutene), polybenzene oxazole, polyimide, epoxy, silicon oxide, silicon nitride, or combinations thereof.

The interposer structure 200 may include an inner area S1 and an outer area S2 defined by the inner area S1. The first semiconductor chip 300, which will be described later, may be disposed on the inner area S1. The mold layer 420, which will be described later, may be disposed on the outer area S2.

A sum of a length R1 of the inner area S1 in the first direction X and a length R2 of the outer area S2 in the first direction X may be equal to a length in the first direction X of the interposer structure 200. The length R1 of the inner area S1 in the first direction X may be greater than the length R2 of the outer area S2 in the first direction X.

The length R1 of the inner area S1 in the first direction X may be equal to a length 300R of the first semiconductor chip 300 in the first direction X. The length R2 of the outer area S2 in the first direction X may be equal to a length 420R of the mold layer 420 in the first direction X. The length 300R of the first semiconductor chip 300 in the first direction X may be greater than the length 420R of the mold layer 420 in the first direction X.

A sum of the length 300R in the first direction X of the first semiconductor chip 300 disposed on the inner area S1 and the length 420R in the first direction X of the mold layer 420 disposed on the outer area S2 may be equal to the length in the first direction X of the interposer structure 200.

A ratio of the length 300R in the first direction X of the first semiconductor chip 300 to the length in the first direction X of the interposer structure 200 may be in a range of 0.9 inclusive to 1 exclusive.

The first semiconductor chip 300 may be disposed on the interposer structure 200. For example, the first semiconductor chip 300 may be disposed on the inner area S1 of the interposer structure 200.

The first semiconductor chip 300 may be an integrated circuit (IC) in which hundreds to millions of semiconductor elements are integrated into one chip. The first semiconductor chip 300 may be a logic chip. For example, the first semiconductor chip 300 may be embodied as a CPU (Central Processing Unit), GPU (Graphic Processing Unit), FPGA (Field-Programmable Gate Array), an application processor (AP) such as a digital signal processor (DSP), a cryptographic processor, a microprocessor, a microcontroller, or ASIC (Application-Specific IC), etc. However, the present disclosure is not limited thereto.

When the ratio of the length 300R in the first direction X of the first semiconductor chip 300 to the length in the first direction X of the interposer structure 200 is in a range of 0.9 inclusive to 1 exclusive, the PI of the first semiconductor chip 300 may be improved. In this regard, the first semiconductor chip 300 may be a logic chip. For example, the first semiconductor chip 300 may be an ASIC chip. In the above case, unlike an existing 2.5D package in which the ASIC chip and the memory chip are mounted on the interposer structure 200, only the ASIC chip may be disposed on the interposer structure 200. When a size of the interposer structure 200 and the ASIC chip size are substantially equal to each other, the ASIC chip may receive power independently. Moreover, when the ASIC chip and the memory chip are mounted on the interposer structure 200, signal noise may occur between the ASIC chip and the memory chip. However, when only the ASIC chip is mounted on the interposer structure 200, the signal noise may be reduced.

Moreover, when the ISC is present in the interposer structure 200, the ISC may operate as the decoupling capacitor to offset the voltage drop effect during the semiconductor chip operation. Thus, the presence of the ISC within the interposer structure 200 may reduce or eliminate the voltage noise to improve the PI of the ASIC chip.

In summary, as power consumption of the ASIC chip is rapidly increasing, there is a need to improve the PI of the ASIC chip. The ASIC chip may be disposed on the interposer structure 200 including the ISC. In this case, the ratio of the length of the ASIC chip in the first direction X to the length of the interposer structure 200 in the first direction X may be in a range of 0.9 inclusive to 1 exclusive. Thus, the PI of the ASIC chip may be improved.

The first semiconductor chip 300 may include a first chip pad 302. The first chip pad 302 may be used to electrically connect the first semiconductor chip 300 with other components. For example, the first chip pad 302 may not be covered with a lower surface of the first semiconductor chip 300 so as to exposed.

The first chip pad 302 may include, but is not limited to, a metal material such as copper (Cu) or aluminum (Al).

The first semiconductor chip 300 may be electrically connected to the interposer structure 200. For example, a plurality of bumps 350 may be formed between the interposer structure 200 and the first semiconductor chip 300. The plurality of bumps 350 may connect the plurality of the second interposer pads 204 to the first chip pads 302, respectively.

Each of the plurality of bumps 350 may be embodied as a solder bump including a low melting point metal, such as tin (Sn) and tin (Sn) alloy. However, the present disclosure is not limited thereto. Each of the plurality of bumps 350 may have various shapes such as a land, a ball, a pin, and a pillar. Moreover, each of the plurality of bump 350 may include UBM (Under Bump Metallurgy).

Each of the plurality of bumps 350 may be formed as a single layer or a stack of multiple layers. When each of the plurality of bumps 350 is formed as the single layer, each of the plurality of bumps 350 may, for example, include tin-silver (Sn—Ag) solder or copper (Cu). When each of the plurality of bumps 350 is formed as the stack of multiple layers, each of the plurality of bumps 350 may include, for example, copper (Cu) filler and solder. However, the technical idea of the present disclosure is not limited thereto, and the number, a spacing between, and an arrangement of the plurality of bumps 350 are not limited to those shown, and may vary depending on the design.

The underfill 410 may fill a space between the first semiconductor chip 300 and the interposer structure 200. The underfill 410 may cover the plurality of bumps 350. The underfill 410 may fill a gap between the first semiconductor chip 300 and the interposer structure 200.

The underfill 410 may include, for example, epoxy-based resin, benzocyclobutene, or polyimide. However, the present disclosure is not limited thereto. For example, the underfill 410 may further include a silica filler. In another example, the underfill 410 may include adhesive and flux. In still another example, the underfill 410 may include a silica filler or flux.

The mold layer 420 may be disposed on the interposer structure 200. For example, the mold layer 420 may be disposed on the outer area S2 on the interposer structure 200. The mold layer 420 may surround the first semiconductor chip 300. The mold layer 420 may cover a side surface of the first semiconductor chip 300. The mold layer 420 may not cover an upper surface of the first semiconductor chip 300.

The mold layer 420 may cover an upper surface 410US of the underfill 410. The mold layer 420 may not cover a side surface 410SW of the underfill 410. The mold layer 420 and the plurality of bumps 350 may not be aligned with each other in a line in the second direction Y.

A side surface 420SW of the mold layer 420 and the side surface 410SW of the underfill 410 may be aligned with each other in a line in the second direction Y. The side surface 410SW of the underfill 410 and a side surface 200SW of the interposer structure 200 may be aligned with each other in a line in the second direction Y.

The side surface 420SW of the mold layer 420, the side surface 410SW of the underfill 410, and the side surface 200SW of the interposer structure 200 may be aligned with each other in a line in the second direction Y. For example, in a view in the first direction X, the side surface 420SW of the mold layer 420, the side surface 410SW of the underfill 410, and the side surface 200SW of the interposer structure 200 may be coplanar with each other.

The mold layer 420 may include, but is not limited to, an insulating polymer material such as epoxy mold compound (EMC). The mold layer 420 may include a material different from that of the underfill 410. For example, the underfill 410 may include an insulating material that has better fluidity than that of the mold layer 420. Accordingly, the underfill 410 may efficiently fill a narrow space between the circuit substrate 100 and the interposer structure 200.

The substrate underfill 430 may fill a space between the interposer structure 200 and the circuit substrate 100. The substrate underfill 430 may cover the first solder ball 250 disposed between the interposer structure 200 and the circuit substrate 100. The substrate underfill 430 may cover a portion of the upper surface 100US of the circuit substrate 100.

The substrate underfill 430 may contact the side surface 410SW of the underfill 410. The substrate underfill 430 may contact a portion or an entirety of the side surface 420SW of the mold layer 420. The substrate underfill 430 may contact the side surface 200SW of the interposer structure 200. In some implementations, on a plane along which the side surface 200SW of the interposer structure 200 extends in the second direction Y, the substrate underfill 430 may contact the side surface 410SW of the underfill 410, the side surface 420SW of the mold layer 420, and the side surface 200SW of the interposer structure 200. The substrate underfill 430, the mold layer 420, and the underfill 410 may contact each other along an intersection line where a boundary face between the mold layer 420 and the underfill 410 and a boundary face between the mold layer 420 and the substrate underfill 430 intersect each other. The substrate underfill 430, the underfill 410, and the mold layer 420 may include different materials.

The substrate underfill 430 may include, for example, epoxy-based resin, benzocyclobutene, or polyimide. However, the present disclosure is not limited thereto. For example, the substrate underfill 430 may further include a silica filler. In another example, the substrate underfill 430 may include adhesive and flux. In still another example, the substrate underfill 430 may include a silica filler or flux.

The stiffener 500 may be disposed on the upper surface 100US of the circuit substrate 100. The stiffener 500 may be spaced apart from the interposer structure 200. The stiffener 500 may be disposed so as to surround the interposer structure 200. The stiffener 500 may not contact the substrate underfill 430. The stiffener 500 may prevent warpage of the circuit substrate 100 from occurring.

The stiffener 500 may include a metal material, such as aluminum (Al), silver (Ag), tin (Sn), gold (Au), nickel (Ni), lead (Pb), titanium (Ti), or alloys thereof, etc. Although not shown, an adhesive layer may be further included between the stiffener 500 and the circuit substrate 100. The adhesive layer may be, for example, a thermally conductive adhesive tape, thermally conductive grease, thermally conductive adhesive, etc.

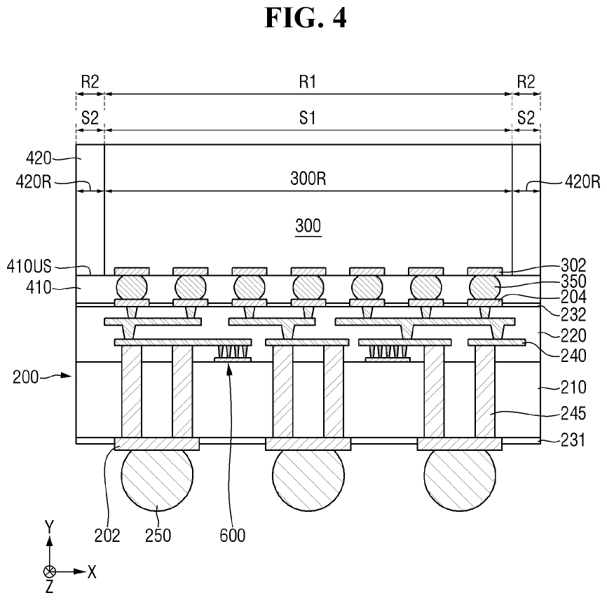

FIG. 4 is a diagram for illustrating a semiconductor package according to some implementations of the present disclosure. For convenience of description, contents that duplicate what has been described using FIG. 1 to FIG. 3 are briefly described or omitted.

Referring to FIG. 4, a semiconductor package according to some implementations may include the interposer structure 200, the first semiconductor chip 300, the underfill 410, and the mold layer 420.

The interposer structure 200 may include the interposer 210, the interlayer insulating film 220, the first passivation film 231, the second passivation film 232, the redistribution layers 240, the through-via 245, the first interposer pad 202, the second interposer pad 204, and the decoupling capacitor 600.

The descriptions of the interposer structure 200 and the first semiconductor chip 300 may be substantially the same as the descriptions in FIGS. 1 to 3.

The decoupling capacitor 600 may be formed between the lowest one of the redistribution layers 240 and the through-via 245. The decoupling capacitor 600 may be formed within the interlayer insulating film 220. The decoupling capacitor 600 may be connected to the lowest one of the redistribution layers 240. In FIG. 4, it is shown that two decoupling capacitors 600 are disposed between the redistribution layers 240. However, the number and a shape of the decoupling capacitors 600 may vary depending on the design.

The interposer structure 200 may include the inner area S1 and the outer area S2 defined by the inner area S1. The first semiconductor chip 300 may be disposed on the inner area S1. The mold layer 420 may be disposed on the outer area S2.

While being disposed on the outer area S2, the mold layer 420 may cover a portion of the side surface of the first semiconductor chip 300 and the upper surface of the underfill 410. The mold layer 420 does not cover the side surface of the underfill 410.

On the outer area S2, the upper surface 410US of the underfill 410 and the lower surface of the first semiconductor chip 300 may be aligned with each other in a line in the first direction X. An angle defined between the upper surface 410US of the underfill 410 and the side surface of the first semiconductor chip 300 on the outer area S2 may be 90 degrees.

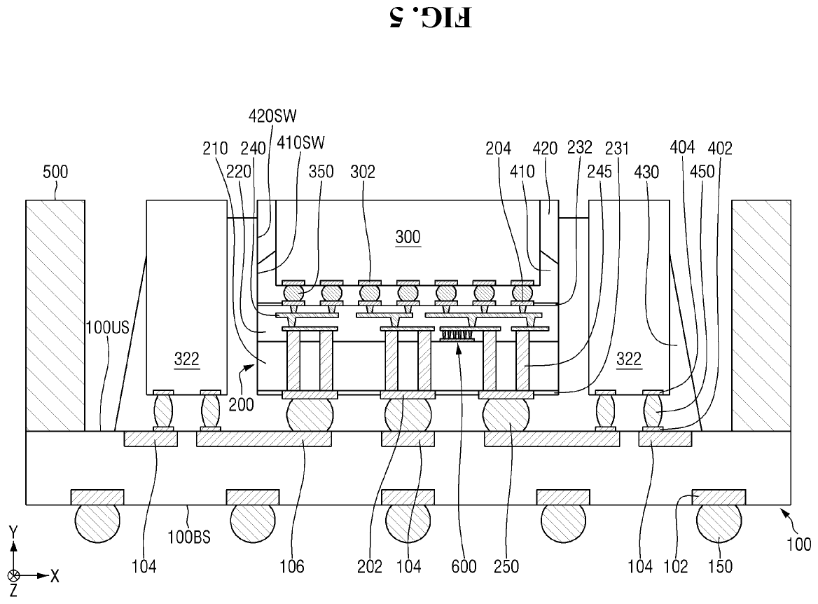

FIG. 5 is a diagram for illustrating a semiconductor package according to some implementations of the present disclosure. For convenience of description, contents that duplicate what has been described using FIG. 1 to FIG. 3 are briefly described or omitted.

Referring to FIG. 5, the semiconductor package according to some implementations may include the circuit substrate 100, the interposer structure 200, the first semiconductor chip 300, a second semiconductor chip 322, the underfill 410, the mold layer 420, the substrate underfill 430, and the stiffener 500.

The circuit substrate 100 may include the first substrate pad 102, the second substrate pad 104, and a bridge 106. In some implementations, the first substrate pad 102 may be formed near the lower surface 100BS of the circuit substrate 100, and the second substrate pad 104 may be formed near the upper surface 100US of the circuit substrate 100. The bridge 106 may be formed between the second substrate pads 104. However, the present disclosure is not limited thereto.

The bridge 106 may be used to electrically connect the circuit substrate 100 to other components. The first semiconductor chip 300 and the second semiconductor chip 322 may be electrically connected to each other via the bridge 106. The interposer structure 200 and the second semiconductor chip 322 may be electrically connected to each other via the bridge 106. The first semiconductor chip 300, the interposer structure 200, and the second semiconductor chip 322 may be electrically connected to each other via the bridge 106. The bridge 106 may be embodied as an embedded interconnect bridge (EMIB). The bridge 106 may include silicon.

A bridge pad 402 may be formed on the bridge 106. The bridge pad 402 may be used to electrically connect the bridge 106 to the second semiconductor chip 322. The bridge pad 402 may include, but is not limited to, a metal material such as copper (Cu) or aluminum (Al). The bridge pad 402 also may be formed on the second substrate pad 104. The bridge pad 402 may be used to electrically connect the second substrate pad 104 to the second semiconductor chip 322.

The second semiconductor chip 322 may be disposed on the circuit substrate 100. The second semiconductor chip 322 may include a second chip pad 404. The description of the second chip pad 404 may be substantially the same as the description of the first chip pad 302 in FIG. 2.

The second semiconductor chip 322 may be electrically connected to the circuit substrate 100. For example, a second solder ball 450 may be formed between the second semiconductor chip 322 and the circuit substrate 100. The second solder ball 450 may connect the bridge pad 402 and the second chip pad 404 to each other. Accordingly, the second semiconductor chip 322 and the circuit substrate 100 may be electrically connected to each other.

The second semiconductor chip 322 may be a memory chip. For example, the second semiconductor chip 322 may be a volatile memory such as dynamic random access memory (DRAM) or static random access memory (SRAM), or may be a non-volatile memory, such as a flash memory, a phase-change random access memory (PRAM), a magnetoresistive random access memory (MRAM), a ferroelectric random access memory (FeRAM), or resistive random access memory (RRAM). In some implementations, the second semiconductor chip 322 may be embodied as a high bandwidth memory (HBM) DRAM semiconductor chip.

The substrate underfill 430 may fill the space between the interposer structure 200 and the circuit substrate 100, a space between the second semiconductor chip 322 and the circuit substrate 100, and a space between the interposer structure 200 and the second semiconductor chip 322. The substrate underfill 430 may contact the side surface 410SW of the underfill and the side surface 420SW of the mold layer 420. The substrate underfill 430 may contact a portion or an entirety of the side surface of the second semiconductor chip 322.

The stiffener 500 may be spaced apart from the second semiconductor chip 322 in the first direction X. The stiffener 500 may not contact the substrate underfill 430.

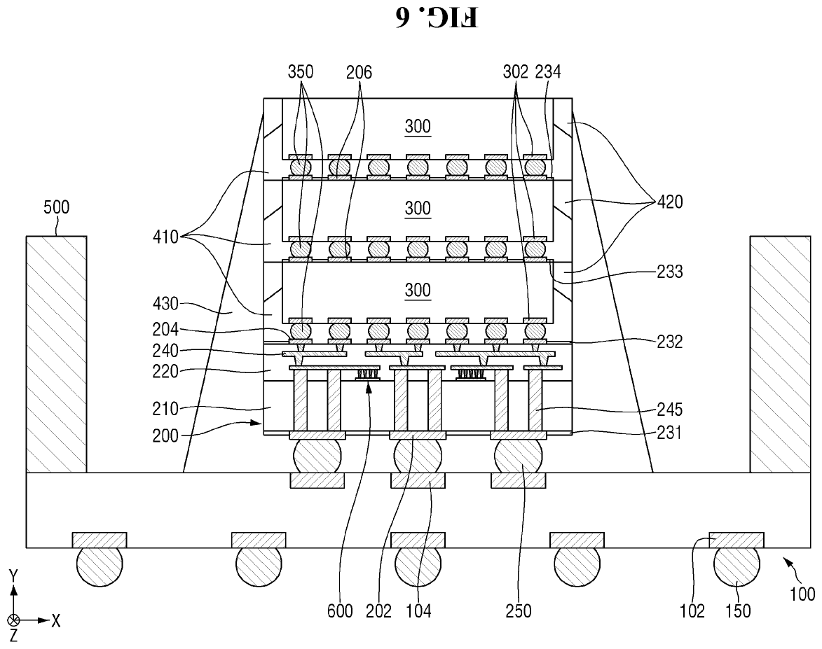

FIG. 6 is a diagram for illustrating a semiconductor package according to some implementations of the present disclosure. For convenience of description, contents that duplicate what has been described using FIGS. 1 to 5 are briefly described or omitted.

Referring to FIG. 6, the semiconductor package according to some implementations may include the circuit substrate 100, the interposer structure 200, a plurality of first semiconductor chips 300, the underfill 410, the mold layer 420, the substrate underfill 430, and the stiffener 500.

The plurality of first semiconductor chips 300 may be stacked vertically on the inner area S1 of the interposer structure 200. The plurality of first semiconductor chips 300 may be connected to the chip connection pad 206 formed on a third passivation layer 233 and a fourth passivation layer 234 via a plurality of bumps 350 and the first chip pads 302. The description about each of the third passivation layer 233 and the fourth passivation layer 234 may be substantially the same as that about the first passivation film 231. The description about the chip connection pad 206 may be substantially the same as the description about the second interposer pad 204. The first semiconductor chip 300 may be a logic chip. In some implementations, the first semiconductor chip 300 may be an ASIC chip.

The underfill 410 and the mold layer 420 may surround the plurality of first semiconductor chips 300. The underfill 410 and the mold layer 420 may be sequentially stacked in the second direction Y. The underfill 410 may cover the upper surface of the mold layer 420, but does not cover the side surface of the mold layer 420.

The substrate underfill 430 may fill a space between the interposer structure 200 and the circuit substrate 100. The substrate underfill 430 may contact the side surfaces of the underfill 410 and the mold layer 420.

As a system bandwidth of each of an artificial intelligence (AI), a high performance computer (HPC), and a server logic chip has rapidly increased, the power consumption of the ASIC chip has increased significantly. Therefore, when designing the power delivery network (PDN), it may be desirable to improve the power integrity (PI) of the logic chip.

According to some implementations of the present disclosure, in order to improve the PI of the ASIC chip, a structure is provided in which the silicon interposer including the ISC is formed so as to have a similar size to a size of the ASIC chip and is vertically connected to the ASIC chip. The ISC in the silicon interposer acts as the decoupling capacitor to offset the voltage drop in supplying power. Moreover, when the semiconductor package operates at high frequencies, switching noise may be reduced. When both the logic chip and the memory chip are not mounted on the silicon interposer, but only the ASIC chip as the logic chip is mounted thereon, the PI of the ASIC chip may be improved.

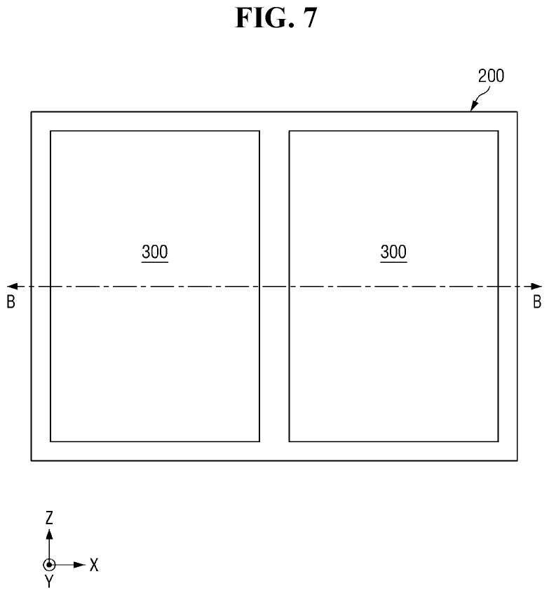

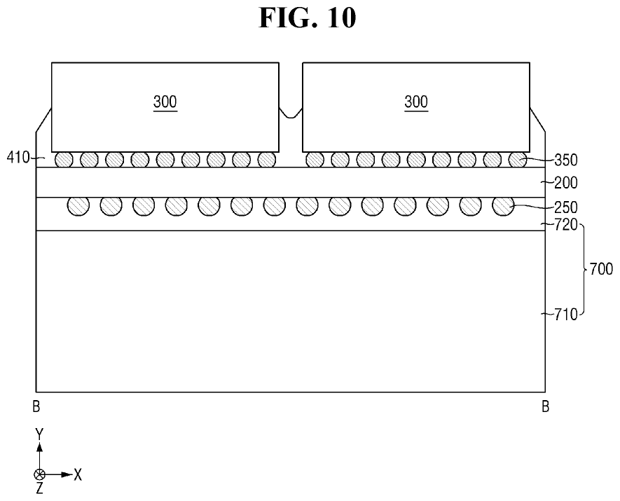

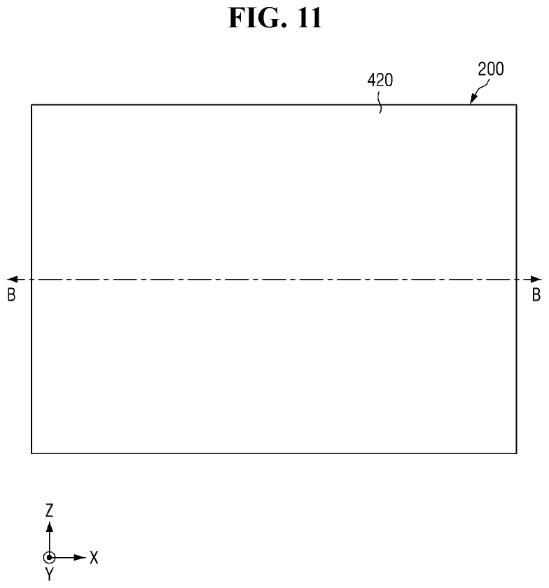

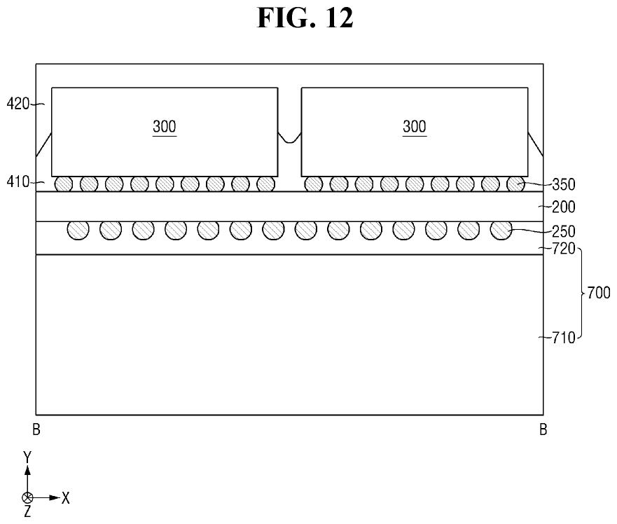

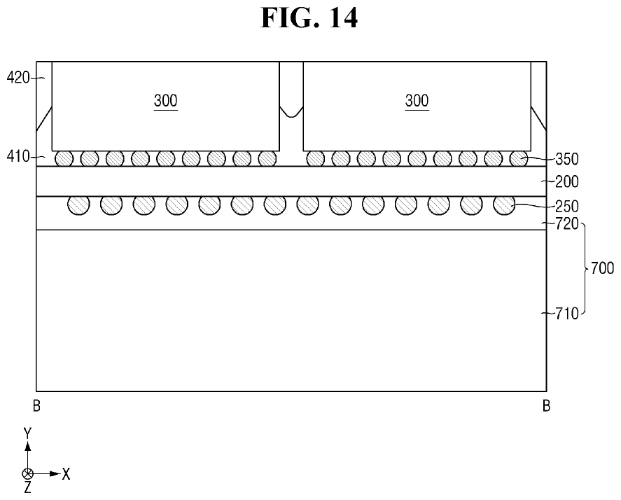

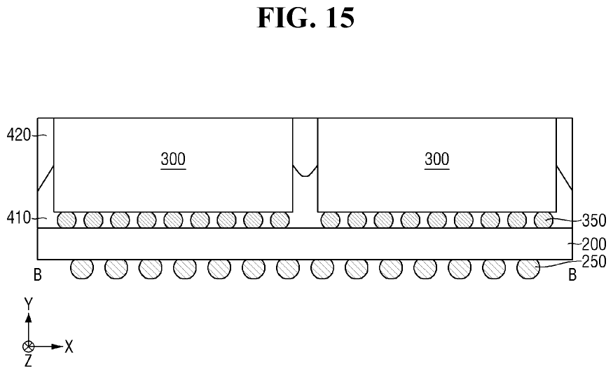

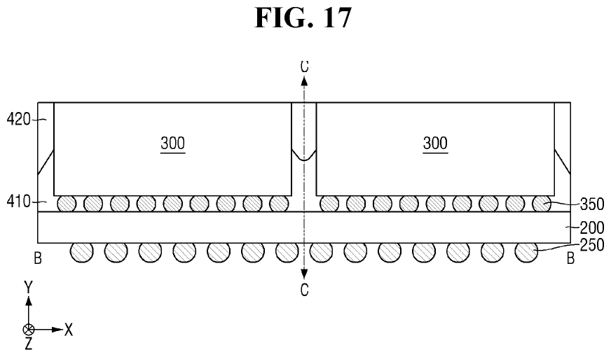

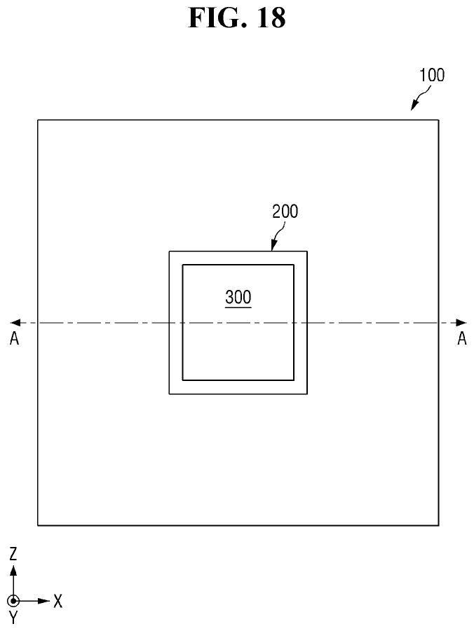

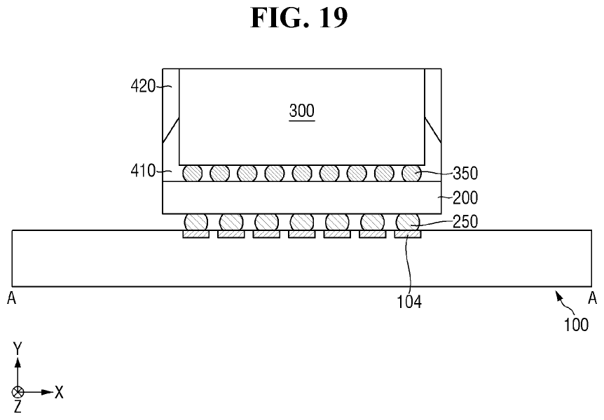

Hereinafter, a method for manufacturing a semiconductor package according to some implementations of the present disclosure is described. FIGS. 7 to 21 are drawings sequentially showing a process of manufacturing a semiconductor package according to some implementations of the present disclosure.

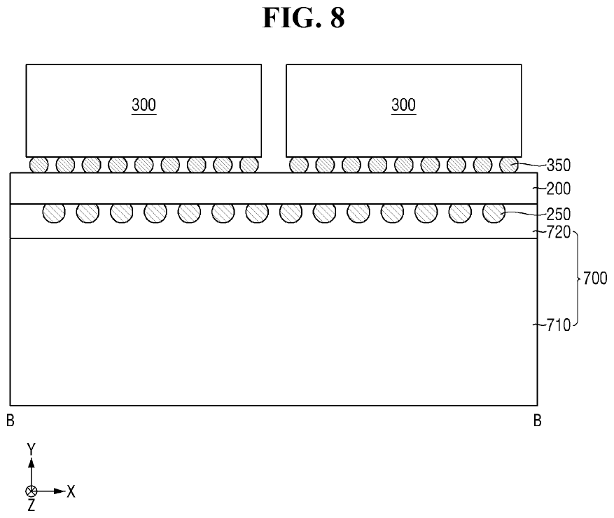

Referring to FIG. 7 and FIG. 8, the first semiconductor chip 300 is mounted on the interposer structure 200. For example, the plurality of bumps 350 electrically connect the interposer structure 200 and the first semiconductor chip 300 to each other. Although not shown, the interposer structure 200 may include the interposer 210, the interlayer insulating film 220, the redistribution layers 240, the through-via 245, and the decoupling capacitor 600 as shown in FIG. 2. The first semiconductor chip 300 may be a logic chip which may be an ASIC chip. The decoupling capacitor 600 may be an integrated stack capacitor (ISC). The interposer structure 200 on which the first solder balls 250 has been formed is attached to a carrier substrate 700. The carrier substrate 700 may be composed of a support substrate 710 and a glue layer 720.

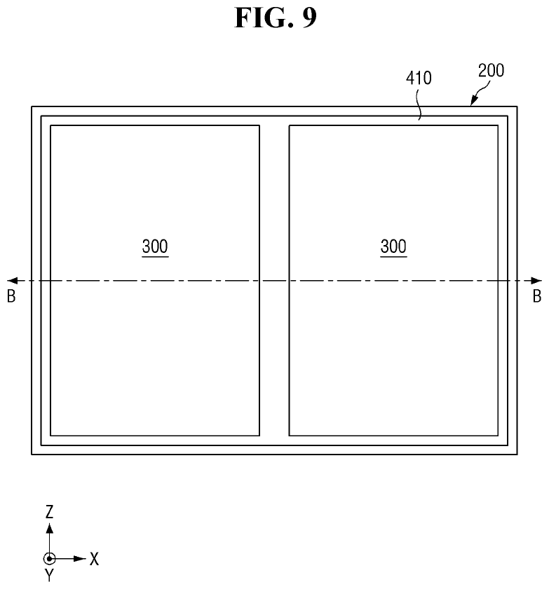

Referring to FIGS. 9 to 12, the underfill 410 is formed on the side surface of the first semiconductor chip 300. The underfill 410 may surround the first semiconductor chip 300. The underfill 410 may fill the space between the first semiconductor chip 300 and the interposer structure 200. The underfill 410 may surround the plurality of bumps 350. Afterwards, the mold layer 420 is formed on the interposer structure 200. The mold layer 420 may be formed on the upper surface of the underfill 410 and the upper surface of the first semiconductor chip 300.

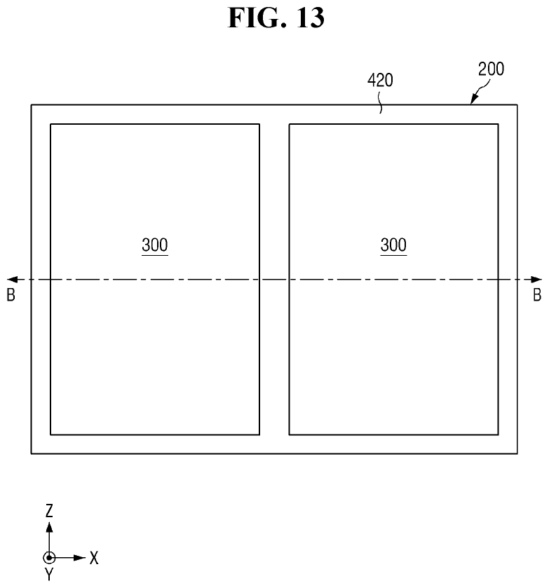

Referring to FIGS. 13 to 15, the upper surface of the first semiconductor chip 300 is exposed by grinding the mold layer 420. Afterwards, the carrier substrate 700 is detached from the interposer structure 200.

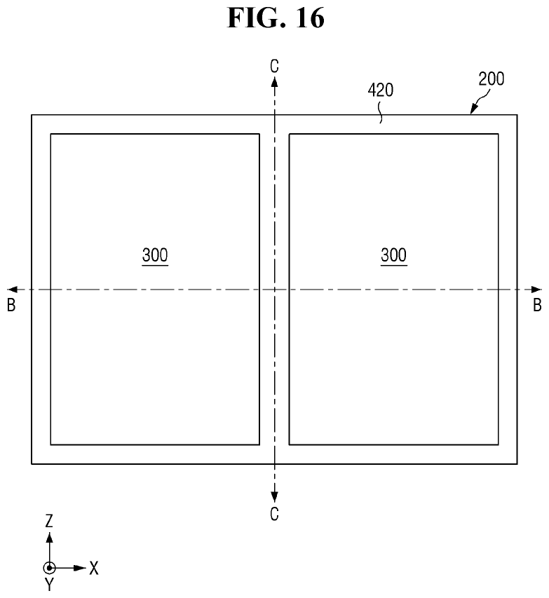

Referring to FIGS. 16 to 19, after cutting a resultant structure along a line C-C, the first semiconductor chip 300 is mounted on the circuit substrate 100. The first semiconductor chip 300 is electrically connected to the circuit substrate 100. For example, the first solder balls 250 may be formed between the first semiconductor chip 300 and the circuit substrate 100 so as to electrically connect the first semiconductor chip 300 and the circuit substrate 100 to each other. For example, the first solder ball 250 may contact the second substrate pad 104 formed in the circuit substrate 100 and the first interposer pad (202 in FIG. 2).

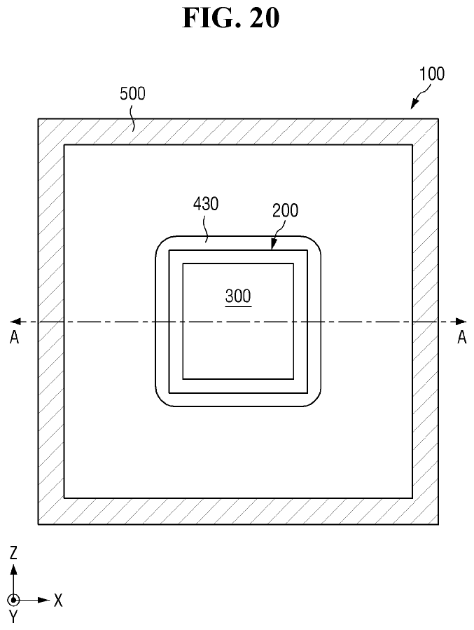

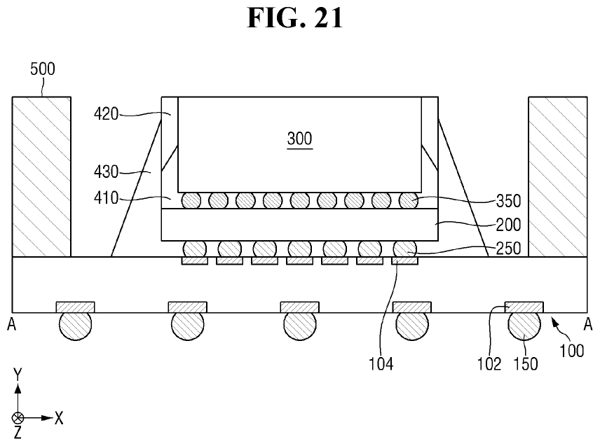

Referring to FIGS. 20 and 21, the substrate underfill 430 is formed between the interposer structure 200 and the circuit substrate 100. The substrate underfill 430 may surround the first solder ball 250. The substrate underfill 430 may cover the side surface of the underfill 410 and the side surface of the mold layer 420. In this case, the substrate underfill 430 may contact the side surface of the underfill 410 and the side surface of the mold layer 420. Afterwards, the circuit substrate 100 and the stiffener 500 are formed. The stiffener 500 may be disposed so as to be spaced apart from the interposer structure 200 in the first direction X. The stiffener 500 may not contact the substrate underfill 430. Afterwards, the connection terminal 150 is formed on the lower surface of the circuit substrate 100.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although some examples of the present disclosure have been described with reference to the accompanying drawings, the present disclosure is not limited to the above examples and may be executed in various different forms. Thus, a person with ordinary skill in the technical field to which the present disclosure belongs will be able to understand that the present disclosure may be implemented in other specific forms without changing the technical idea or essential characteristics of the present disclosure. Therefore, it should be understood that the examples as described above are not restrictive but illustrative in all respects.

What is claimed is:

1. A semiconductor package comprising:
an interposer structure extending in a first direction, wherein the interposer structure includes an inner area and an outer area defined by the inner area;
a first semiconductor chip mounted on the inner area and electrically connected to the interposer structure;
a plurality of bumps disposed between the first semiconductor chip and the interposer structure, wherein the plurality of bumps contact each of the first semiconductor chip and the interposer structure;
an underfill filling a space between the interposer structure and the first semiconductor chip and covering the plurality of bumps; and
a mold layer disposed on the outer area and surrounding the first semiconductor chip,
wherein the interposer structure includes a decoupling capacitor,
wherein a ratio of a length in the first direction of the first semiconductor chip to a length in the first direction of the interposer structure is 0.9 or greater and less than 1, and
wherein the length in the first direction of the interposer structure is the same as a sum of the length in the first direction of the first semiconductor chip and a length in the first direction of the mold layer.

2. The semiconductor package of claim 1, wherein the interposer structure includes:
an interposer extending in the first direction;
an interlayer insulating film disposed on the interposer,
a through-via extending through the interposer and to the interlayer insulating film; and
redistribution layers within the interlayer insulating film,
wherein the decoupling capacitor is within the interlayer insulating film and below a lowest layer of the redistribution layers.

3. The semiconductor package of claim 2, wherein the first semiconductor chip is an application specific integrated circuit (ASIC) chip, and
wherein the decoupling capacitor is an integrated stack capacitor (ISC).

4. The semiconductor package of claim 1, wherein the mold layer covers an upper surface of the underfill and does not cover a side surface of the underfill.

5. The semiconductor package of claim 1, comprising:
a circuit substrate on which the interposer structure is disposed; and
a plurality of first solder balls disposed between the interposer structure and the circuit substrate.

6. The semiconductor package of claim 5, comprising a substrate underfill filling a space between the interposer structure and the circuit substrate and covering the plurality of first solder balls,
wherein the substrate underfill is in contact with a side surface of the underfill and a side surface of the mold layer.

7. The semiconductor package of claim 6, wherein, on a plane along which a side surface of the interposer structure extends in a second direction intersecting the first direction, the substrate underfill is in contact with the side surface of the underfill, the side surface of the mold layer, and the side surface of the interposer structure.

8. The semiconductor package of claim 6, wherein the substrate underfill, the underfill, and the mold layer include different materials from one other.

9. The semiconductor package of claim 6, comprising a stiffener disposed on an upper surface of the circuit substrate and spaced apart from the interposer structure,
wherein the stiffener is spaced apart from the substrate underfill.

10. A semiconductor package comprising:
a circuit substrate extending in a first direction;
an interposer structure disposed on the circuit substrate, wherein the interposer structure includes an inner area and an outer area defined by the inner area;
a plurality of first solder balls disposed between the circuit substrate and the interposer structure, wherein the plurality of first solder balls connect the circuit substrate and the interposer structure to one another;
a first semiconductor chip mounted on the inner area and electrically connected to the interposer structure;
a plurality of bumps disposed between the first semiconductor chip and the interposer structure, wherein the plurality of bumps contact each of the first semiconductor chip and the interposer structure;
an underfill filling a space between the interposer structure and the first semiconductor chip and covering the plurality of bumps; and
a mold layer disposed on the outer area and surrounding the first semiconductor chip, wherein the mold layer covers an upper surface of the underfill,
wherein the interposer structure includes:
an interposer extending in the first direction,
an interlayer insulating film disposed on the interposer,
a through-via extending through the interposer and to the interlayer insulating film,
redistribution layers within the interlayer insulating film, and
a decoupling capacitor within the interlayer insulating film,
wherein a ratio of a length in the first direction of the first semiconductor chip to a length in the first direction of the interposer structure is 0.9 or greater and less than 1, and
wherein the length in the first direction of the interposer structure is the same as a sum of the length in the first direction of the first semiconductor chip and a length in the first direction of the mold layer.

11. The semiconductor package of claim 10, wherein the first semiconductor chip is an ASIC chip, and
wherein the decoupling capacitor is an integrated stack capacitor.

12. The semiconductor package of claim 10, comprising:
a second semiconductor chip disposed on the circuit substrate and spaced apart from the interposer structure in the first direction; and
a first bridge in the circuit substrate,
wherein the interposer structure, the first semiconductor chip, and the second semiconductor chip are electrically connected to one another via the first bridge.

13. The semiconductor package of claim 12, comprising a plurality of second solder balls disposed between the first bridge and the second semiconductor chip, wherein the plurality of second solder balls connect the first bridge and the second semiconductor chip to one another.

14. The semiconductor package of claim 12, comprising a substrate underfill filling a space between the interposer structure and the circuit substrate, a space between the second semiconductor chip and the circuit substrate, and a space between the interposer structure and the second semiconductor chip.

15. The semiconductor package of claim 14, wherein the substrate underfill is in contact with a side surface of the underfill and a side surface of the mold layer.

16. The semiconductor package of claim 15, wherein the substrate underfill, the mold layer, and the underfill include different materials from one another.

17. The semiconductor package of claim 14, comprising a stiffener disposed on the circuit substrate,
wherein the stiffener is spaced apart from the interposer structure and the second semiconductor chip and is spaced apart from the substrate underfill.

18. A semiconductor package comprising:
a circuit substrate;
an interposer structure disposed on the circuit substrate, wherein the interposer structure includes:
an interposer extending in a first direction,
an interlayer insulating film disposed on the interposer,
a through-via extending through the interposer and to the interlayer insulating film,
redistribution layers within the interlayer insulating film, and
an integrated stack capacitor within the interlayer insulating film and between the through-via and a lowest one of the redistribution layers;
a plurality of solder balls disposed between the circuit substrate and the interposer structure, wherein the plurality of solder balls connect the circuit substrate and the interposer structure to one another;
an ASIC chip disposed on the interposer structure;
a plurality of bumps disposed between the ASIC chip and the interposer structure, wherein the plurality of bumps connect the ASIC chip and the interposer structure to one another;
an underfill filling a space between the interposer structure and the ASIC chip and covering the plurality of bumps;
a mold layer surrounding the underfill and the ASIC chip, wherein the mold layer covers an upper surface of the underfill;
a substrate underfill covering a portion of the upper surface of the circuit substrate and contacting a side surface of the interposer structure, a side surface of the underfill, and a side surface of the mold layer; and
a stiffener spaced apart from the interposer structure and the ASIC chip,
wherein the interposer structure includes an inner area and an outer area defined by the inner area,
wherein the ASIC chip is disposed on the inner area, and the mold layer is disposed on the outer area,
wherein a sum of a length in the first direction of the inner area and a length in the first direction of the outer area is the same as a length in the first direction of the interposer structure, and
wherein the side surface of the mold layer, a side surface of the underfill, and the side surface of the interposer structure are coplanar with one another.

19. The semiconductor package of claim 18, wherein the substrate underfill, the underfill, and the mold layer include different materials from one another.

20. The semiconductor package of claim 18, wherein the substrate underfill, the mold layer, and the underfill contact one another along an intersection line along which a boundary face between the mold layer and the underfill and a boundary face between the mold layer and the substrate underfill intersect one another.
